(19) United States
(12) Patent Application Publication
(10) Pub. No.: US 2007/0134915 A1
(43) Pub. Date: Jun. 14, 2007

(54) METHOD OF FABRICATING A METAL LINE IN A SEMICONDUCTOR DEVICE

(76) Inventor: Han-Choon Lee, Seoul (KR)

Correspondence Address: SHERR & NOURSE, PLLC, 620 HERNDON PARKWAY, SUITE 200, HERNDON, VA, 20170, US

(21) Appl. No.: 11/609,864

(22) Filed: Dec. 12, 2006

(30) Foreign Application Priority Data
Dec. 14, 2005 (KR) 10-2005-0123283

(51) Int. Cl. H01L 21/4763

(52) U.S. Cl. 438/629; 257/E21.579

(57) ABSTRACT

A method for forming a metal line of a semiconductor device may include cleaning a via and/or a trench with B₂H₆ gas to remove Fluorine. Cleaning step may be performed at a temperature between approximately 100° C. and approximately 500° C.

The present application claims priority under 35 U.S.C. 119 and 35 U.S.C. 365 to Korean Patent Application No. 10-2005-0123283 (filed on Dec. 14, 2005), which is hereby incorporated by reference in its entirety.

### BACKGROUND

In high-speed and/or high-integration semiconductor devices, metal lines may be finer and/or may have multiple layers. As widths of metal lines are reduced, signal delay may occur due to the resistance and the capacitance of the metal line. To reduce signal delay, Copper having a low resistance may be employed as part of metal wiring.

Copper may be relatively difficult to etch. Copper wiring may be formed through a damascene process, which may not require etching of Copper. A damascene process may include at least one of: forming a trench; forming a Copper layer inside the trench; and/or performing chemical mechanical polishing.

In comparison with some other metals, Copper may be difficult to etch. To avoid etching, Copper wiring may be formed through a damascene process, including the steps of: forming a trench; forming a Copper layer to fill the trench; and chemical mechanical polishing the copper layer. A trench may be formed by an etching process using a photoresist film. A process gas (e.g. Fluorine (F)) may be used to etch a trench.

After the etching process is completed, Fluorine gas may be discharged. However, it may be difficult to completely discharge Fluorine gas from a via or an insulating film. The remaining Fluorine gas may react with C₂F₆, CF₄ or similar material used in subsequent processes to generate CF based residues.

Undischarged Fluorine gas and/or residues may deteriorate the electrical characteristic of a device and hinder a diffusion barrier film from being appropriately (e.g. uniformly) deposited. Some undischarged Fluorine gas and/or residues may be removed using a H₂ cleaning process, H₂ heat treatment or similar process. However, it is difficult to discharge all Fluorine and residues from a H₂ cleaning process.

### SUMMARY

Embodiments relate to a method of forming a metal line in a semiconductor device. Embodiments relate to a method of manufacturing a semiconductor device having copper wiring. Embodiments relate to a method of forming a metal line capable of good electrical characteristic. Embodiments relate to uniformly depositing a diffusion barrier film.

Embodiments relate to a method of forming a metal line in a semiconductor device, including at least one of the following steps: forming an interlayer insulating film over a semiconductor substrate; forming a via over an interlayer insulating film; forming a trench through which a via is exposed; cleaning a via and a trench with B₂H₆ gas; and forming a metal line including a diffusion barrier film and a Copper layer by filling a via and a trench.

### BRIEF DESCRIPTION OF THE DRAWINGS

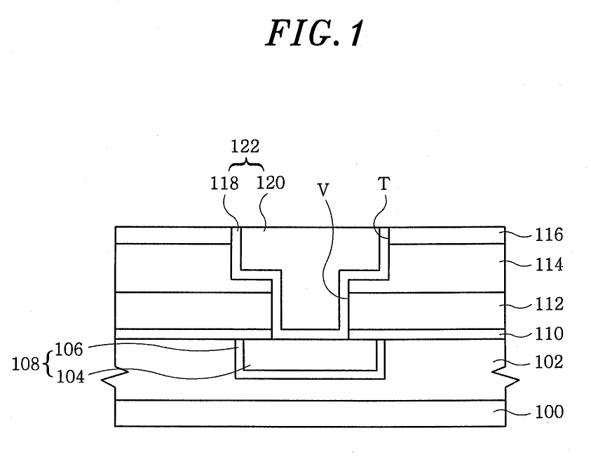

Example FIG. 1 illustrates a cross sectional view of a metal line of a semiconductor device, in accordance with embodiments.

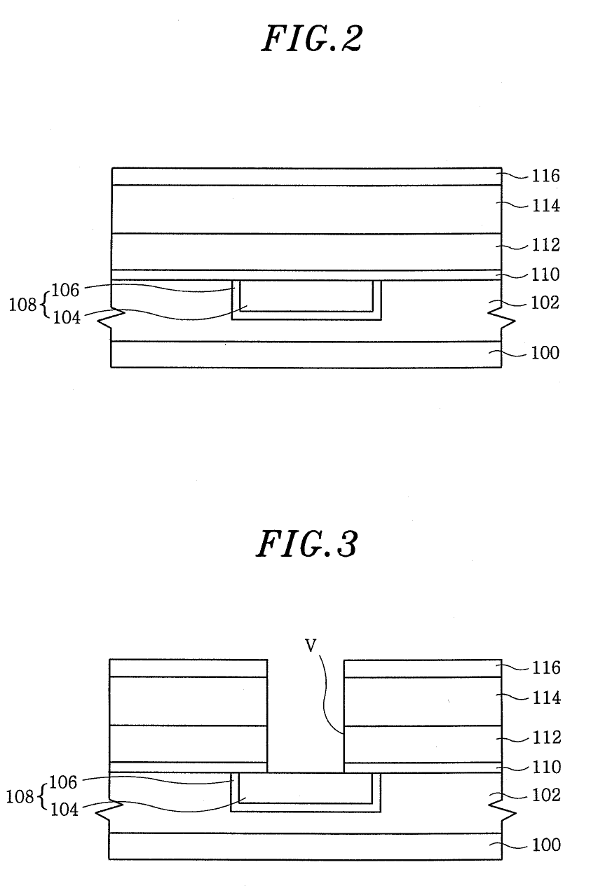

Example FIGS. 2 to 5 show cross sectional views illustrating forming metal lines in a semiconductor device, in accordance with embodiments.

### DETAILED DESCRIPTION

Example FIG. 1, illustrates a cross sectional view of a metal line of a semiconductor device, in accordance with embodiments. As illustrated in FIG. 1, first interlayer insulating film 102 may be formed over substrate 100 and/or etch stop film 110. Second interlayer insulating film 112, third interlayer insulating film 114, and/or fourth interlayer insulating film 116 may be stacked over first interlayer insulating film 102.

Substrate 100 may include individual devices (not shown) and/or lower wiring 108. Lower wiring 108 may include first diffusion barrier metal layer 104 and/or Copper layer 106. Etch stop film 110 may include SiN, SiH₄, and/or a similar material.

First interlayer insulating film 102, second interlayer insulating film 112, third interlayer insulating film 114, and/or fourth interlayer insulating film 116 may be formed by depositing an organic or inorganic insulating material. Examples of organic or inorganic insulating materials are fluorine silicate glass (FSG), undoped silicate glass (USG), SiH₄, a tetra ethylortho silicate (TEOS), or other similar materials.

First interlayer insulating film 102, second interlayer insulating film 112, third interlayer insulating film 114, and/or fourth interlayer insulating film 116 may be formed of a low-k material. An example of a low-k material include black diamond (BD) (e.g. having a dielectric constant less than approximately 3.0).

In embodiments, first interlayer insulating film 102 may be formed of FSG. In embodiments, second interlayer insulating film 112 may be formed of SiH₄. In embodiments, third interlayer insulating film 114 may be formed of FSG. In embodiments, fourth interlayer insulating film 116 may be formed of SiH₄. Each of first interlayer insulating film 102, second interlayer insulating film 112, third interlayer insulating film 114, and/or fourth interlayer insulating film 116 may be a single layer film or a multi layer film.

Trench T may be formed through third interlayer insulating film 114 and/or fourth interlayer insulating film 116. Via V may be formed through etch stop film 110, second interlayer insulating film 112, third interlayer insulating film 114, and/or fourth interlayer insulating film 116. Via V may expose lower wiring 108. Trench T may expose via V.

Metal line 122 may be formed inside via V and trench T Metal line 122 may be for individual devices or electrical interconnections. Metal line 122 may include second diffusion layer 118 formed on the sidewalls of via V and trench T. Metal line 122 may include metal layer 120 that may fill via V and/or trench T. Metal layer 120 may be formed over second diffusion layer 118. In embodiments, second diffusion barrier metal layer 118 may be formed of Ta, TaN, and/or TaSiN.

Example FIGS. 2 to 4 show cross sectional views illustrating forming a metal line, in accordance with embodiments. As illustrated in FIG. 2, etch stop layer 110, second interlayer insulating film 112, third interlayer insulating film 114, and/or fourth interlayer insulating film 116 may be stacked over substrate 100. First interlayer insulating film 102 may be formed over substrate 100. Lower wiring 108 may be made of Copper. Lower wiring 108 may be embedded in first interlayer insulating film 102. Etch stop layer 110, second interlayer insulating film 112, third interlayer insulating film 114, and/or fourth interlayer insulating film 116 may include at least one of SiN, SiH₄, and/or FSG.

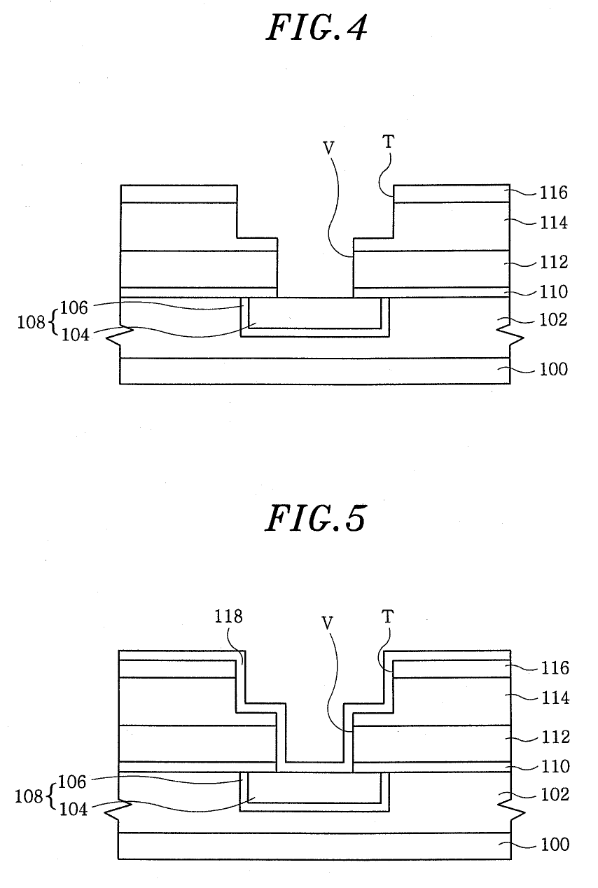

As illustrated in FIG. 3, via V may be formed by a selective etching process. A selective etching process may use a photoresist film formed over fourth interlayer insulating film 116 to expose at least a portion of etch stop film 110. Via V may be formed by a dry etching process using a gas containing F (e.g. C₂F₆ and/or CF₄) As illustrated in FIG. 4, trench T may be formed by a selective etching process using a photoresist film to expose via V. Trench T may be formed by a drying etching process using a process gas containing F. An exposed portion of etch stop film 110 may be removed.

When via V and/or trench T are etched by a gas including Fluorine, remaining Fluorine gas and/or residues (e.g. SiOF and/or CuO) may attach to the bottom and/or the sidewalls of via V and/or trench T. Remaining Fluorine gas may be removed by B₂H₆ gas, in accordance with embodiments.

In embodiments, Fluorine gas that remains in via V and/or trench T may be removed by injecting B₂H₆ gas into via V and/or trench T while maintaining substrate 100 at a temperature between approximately 100° C. and approximately 500° C. SiOF may be separated into BF and SiO₂ by injecting B₂H₆ gas and/or CuO may react with Hydrogen to produce H₂O. H₂O may be drained from a chamber. Remaining Fluorine may be removed in the form of BF and/or HF. Since B₂H₆ gas has a relatively high reaction energy with respect to F, B₂H₆ gas reacts with Fluorine contained in residues and/or F gas to generate a new material that may be relatively easy to discharge (e.g. in the form of a gas) from a process chamber, in accordance with embodiments.

As illustrated in FIG. 5, diffusion barrier metal layer 118 and cooper layer 120 (e.g. as illustrated in FIG. 1) may be formed on the sidewalls of via V and/or trench T. Diffusion barrier metal layer 118 may be formed by sputtering. A substrate structure may be planarized through chemical mechanical polishing until the interlayer insulating film 116 is exposed to form metal line 122 (e.g. including diffusion barrier layer 118 and Copper layer 120).

In embodiments, Fluorine remaining in a via and/or a trench may be removed. Removal of fluorine may clean the sidewalls of a via and/or a trench, in accordance with embodiments. Removal of Fluorine may allow for the formation of a uniform diffusion barrier layer, in accordance with embodiments.

A diffusion barrier layer may be formed uniformly by substantially removing all of Fluorine remaining from an etching process from a via and/or a trench, in accordance with embodiments. A uniformly formed diffusion barrier lay may allow for Copper to fill a via and/or a trench properly, in accordance with embodiments. Properly filling a via and/or a trench may prevent wiring disconnections and may contribute to the reliability of a device, in accordance with embodiments.

It will be apparent to those skilled in the art that various modifications and variations can be made to embodiments. Thus, it is intended that embodiments cover modifications and variations thereof within the scope of the appended claims.

What is claimed is:

1. A method comprising:
forming at least one structure in at least one insulating film formed over a semiconductor substrate; and
exposing said at least one structure to B₂H₆ gas.

2. The method of claim 1, wherein the method comprises forming a metal line in a semiconductor device.

3. The method of claim 1, wherein said at least one structure comprises at least one of a via and a trench.

4. The method of claim 1, wherein said forming at least one structure comprises forming a via in said at least one insulating film;

5. The method of claim 4, wherein said forming at least one structure comprises forming a trench in said at least one insulating film.

6. The method of claim 5, wherein the via is exposed at the bottom of the trench.

7. The method of claim 1, comprising forming a metal line in said at least one structure.

8. The method of claim 7, wherein the metal line comprises at least one of a diffusion barrier film and a Copper layer.

9. The method of claim 1, wherein the exposing at least one structure to B₂H₆ gas is performed while maintaining the semiconductor substrate at a temperature between approximately 100° C. and approximately 500° C.

10. The method of claim 1, wherein said exposing said at least one structure to B₂H₆ gas generates at least one of SiOF, F and CuO in said at least one structure.

11. The method of claim 10, comprising removing at least one of SiOF, F and CuO from said at least one structure.

12. A method comprising:
forming at least one interlayer insulating film over a semiconductor substrate;
forming at least one structure in said at least one interlayer insulating film by etching using a gas comprising Fluorine; and
removing excess Fluorine from said at least one structure using a material having a high reaction energy with respect to Fluorine.

13. The method of claim 12, wherein said at least one structure comprises at least one of a via and a trench.

14. The method of claim 12, wherein the material having a high reaction energy with respect to fluorine comprises B₂H₆ gas.

15. The method of claim 12, wherein said removing is performed at a temperature between approximately 100° C. and approximately 500° C.

16. The method of claim 12, wherein said removing comprises removing at least one of SiOF, F, and CuO from said at least one structure.
